(19) United States
(12) Patent Application Publication
(10) Pub. No.: US 2026/0025944 A1
(43) Pub. Date: Jan. 22, 2026

(54) Tool-Less Fan-Bracket Assembly For Server

(71) Applicant: Quanta Computer Inc., Taoyuan City (TW)

(72) Inventors: Yaw-Tzorng Tsorng, Taoyuan City (TW); Tung-Hsien Wu, Taoyuan City (TW); Hsiang-Pu Ni, Taoyuan City (TW); Yao-Lin Zhang, Taoyuan City (TW)

(21) Appl. No.: 18/777,471

(22) Filed: Jul. 18, 2024

(51) Int. Cl. H05K 7/20; H05K 7/14

(52) U.S. Cl. CPC H05K 7/20172; H05K 7/1491; H05K 7/20736

(57) ABSTRACT

A fan-bracket assembly for use in a chassis of a server comprises a baffle, a tray, a plurality of fan cages, and a first cable-routing channel. The baffle has mounting portions configured for mounting the fan-bracket assembly within the chassis. The tray is coupled to the baffle and includes a groove. Each fan cage is configured for receiving a fan to move air within the server. Each fan cage includes a protruding section that is received within the groove of the tray such that each fan cage is movable along the tray. Each fan cage includes a locking element for locking the corresponding fan cage at an operational position relative to the tray. The first cable-routing channel is partially defined by an external surface of a first fan cage. The first cable-routing channel receives a cable that extends from one side of the fan-bracket assembly to an opposing side.

### FIELD OF THE INVENTION

The present invention relates generally to a fan module for delivering cooling air within a server, and more specifically, to a fan-bracket assembly that provides modularity to the fan arrangement to allow for cable-routing channels at different locations within the server.

### BACKGROUND OF THE INVENTION

Server products contain various types of electronic equipment that are mounted on a server chassis. The server often includes numerous processors and/or memory devices, such as dual in-line memory modules (“DIMM” components). As the function of these electronics increases, the power consumption increases; therefore leading to the generation of higher levels of waste heat. Furthermore, the physical space within server chassis is confined, such that there is a limited volume for fans, air ducts, and cables/wires that connect the electronic equipment. As the market demands higher computing power and larger memory storage within smaller volumes, a need exists for components within the server that can efficiently remove heat and assist in routing the cables and wires that connect the various pieces of electronic equipment.

Many servers rely on forced air convection to keep the components at the proper working temperature. Fans are located in the server chassis to draw cool air into the chassis, move the cool air past the components, and expel the heated air from the chassis. Because the fans extend across the chassis to maximize the air movement and cooling capacity, there is often problems positioning the cables between the fans. To account for routing of the cables, cable channels are provided at fixed locations in the fan module bracket. However, because different server models have different cable routing requirements, different fan modules must be manufactured with different cable-routing channels to meet the cable-routing requirements.

For example, FIGS. 1A and 1B illustrate a prior art fan-bracket assembly 10 with a plurality of fan cages 12 that receive fans. A front wall 14 of the prior art fan-mounting bracket 10 includes three separate cable routing channels 16.

FIGS. 2A and 2B illustrate a different prior art fan-bracket assembly 20 with a plurality of fan cages 22 that receive fans for use in a different server. A front wall 24 of the prior art fan-mounting bracket 20 includes two cable routing channels 26, as shown best in FIG. 2A. In addition to the number of cable-routing channels 26 being different, the two cable routing channels 26 in FIGS. 2A-2B are not of the same size as the three cable routing channels 16 in FIG. 1A-1B. As such, in accordance with prior art systems, different fan-bracket assemblies 10 and 20 must be manufactured to accommodate the different cable routing requirements for two different servers, which results in increased manufacturing costs and additional inventories of products.

The present disclosure is directed to an improved fan-bracket assembly for a server that can be arranged into various configurations to allow for different locations and different sizes for the cable-routing channels.

### SUMMARY OF THE INVENTION

The term embodiment and like terms are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings and each claim.

According to one aspect of the present disclosure, a fan-bracket assembly for use in a chassis of a server comprises a baffle, a tray, a plurality of fan cages, and a first cable-routing channel. The baffle has mounting portions configured for mounting the fan-bracket assembly within the chassis of the server. The tray is coupled to the baffle and includes a groove. Each of the plurality of fan cages is configured for receiving a fan to move air within the chassis of the server. Each of the plurality of fan cages includes a protruding section that is received within the groove of the tray such that each of the plurality of fan cages is movable along the tray. Each of the plurality of fan cages includes a locking element for locking the corresponding fan cage at an operational position relative to the tray. The first cable-routing channel is partially defined by a first external surface of a first one of the plurality of fan cages. The first cable-routing channel is for receiving a first electronics cable that extends from one side of the fan-bracket assembly to an opposing side of the fan-bracket assembly.

According to a configuration of the above implementation, the first cable-routing channel is located between the first one of the plurality of fan cages and a second one of the plurality of fan cages. The first cable-routing channel is further defined by a second external surface of the second one of the plurality of fan cages.

According to another configuration of the above implementation, the fan-bracket assembly further includes a second cable-routing channel partially defined by a second external surface of a second one of the plurality of fan cages. The second cable-routing channel is for receiving a second electronics cable that extends from the one side of the fan-bracket assembly to the opposing side of the fan-bracket assembly.

According to a further configuration of the above implementation, the mounting portions of the baffle including openings for receiving fasteners that mount the fan-bracket assembly within the chassis of the server.

In a further aspect of the above implementation, the locking element includes a hand-actuated plunger that transitions between: (i) an open position that allows the corresponding fan cage to be moved along the tray; and (ii) a closed position in which the corresponding fan cage is locked in the operational position. The hand-actuated plunger transitions between the open position and the closed position without the use of a tool.

In yet a further aspect of the above implementation, the hand-actuated plunger engages one of a plurality of openings on the baffle in the closed position.

In another aspect of the above implementation, each of the plurality of fan cages includes at least one of a rib and a slit for mating with corresponding features of the fan.

According to a further configuration of the above implementation, the baffle includes a plurality of flanges that correspond to the plurality of fan cages. Each of the plurality of flanges includes a plurality of mating features for allowing the corresponding fan cage to be mated to the baffle at a plurality of locations.

According to another configuration of the above implementation, the tray is coupled to the baffle through a plurality of rivets.

In yet a further aspect of the above implementation, the tray includes a closed end and an open end. The groove extends between the closed end and the open end. Each of the plurality of fan cages is insertable into the groove at the open end of the tray and movable toward the closed end of the tray.

In another aspect of the present disclosure, a fan-bracket assembly for use in servers comprises, a baffle, a tray, and a plurality of fan cages. The tray is coupled to the baffle and includes a groove. Each of the plurality of fan cages is configured for receiving a fan. Each of the plurality of fan cages includes a protruding section that is received within the groove of the tray such that each of the plurality of fan cages is movable along the tray. Each of the plurality of fan cages includes a locking element for locking the corresponding fan cage relative to the tray. In a first configuration, the plurality of fan cages is positioned on the tray to form a first cable-routing channel partially defined by at least a first one of the plurality of fan cages. In a second configuration, the plurality of fan cages is positioned on the tray to form a second cable-routing channel partially defined by at least a second one of the plurality of fan cages. The second cable-routing channel is at a different location relative to the tray than the first cable-routing channel. Each of the first and second cable-routing channels is capable of receiving an electronics cable that extends from one side of the fan-bracket assembly to an opposing side of the fan-bracket assembly.

According to another aspect of the above implementation, in the first configuration, the first cable-routing channel is partially defined by the first one of the plurality of fan cages and a third one of the plurality of fan cages.

According to a further aspect of the above implementation, in the second configuration, the second cable-routing channel is partially defined by the second one of the plurality of fan cages and a fourth one of the plurality of fan cages.

According to yet a further aspect of the above implementation, the baffle has mounting portions adapted for mounting the fan-bracket assembly to: (i) a first server when the fan-bracket assembly is in the first configuration; and (ii) a second server when the fan-bracket assembly is in the second configuration.

According to another configuration of the above implementation, the tray is coupled to the baffle through a plurality of fasteners.

According to another configuration of the above implementation, the locking element includes a hand-actuated plunger that moves between: (i) an open position that allows the corresponding fan cage to be moved along the tray; and (ii) a closed position in which the corresponding fan cage is locked in a first operational position for the first configuration or locked in a second operational position for the second configuration.

In a further aspect of the present disclosure, a server comprises a chassis having a base and side walls extending upwardly from the base, electronics located within the chassis, a first cable and a second cable coupled to the electronics, a tray, a plurality of fan cages, and a plurality of fans. The tray fixed within the chassis, the tray including a groove. Each of the plurality of fan cages includes a protruding section that is received within the groove of the tray such that each of the plurality of fan cages is movable along the tray. Each of the plurality of fan cages including a locking element for locking the corresponding fan cage relative to the tray. Each of the plurality of fans is mounted within a corresponding one of the plurality of fan cages. The plurality of fan cages is movable along the tray to form: (i) a first configuration having a first cable-routing channel partially defined by at least a first one of the plurality of fan cages and for receiving at least one of the first and second cables; and (ii) a second configuration having a second cable-routing channel partially defined by at least a second one of the plurality of fan cages and for receiving at least one of the first and second cables. The second cable-routing channel is at a different location within the chassis than the first cable-routing channel.

According to a further aspect of the above implementation, the server further includes a baffle having mounting portions that are mounted to the chassis of the server. The tray is fixed to the baffle.

According to yet a further aspect of the above implementation, each of the locking elements for the plurality of fan cages is a hand-actuated plunger that allows the plurality of fan cages to be movable along the tray and locked into an operational position without the use of tools.

According to another aspect of the above implementation, in the first configuration, the first cable-routing channel is partially defined by the first one of the plurality of fan cages and a third one of the plurality of fan cages. In the second configuration, the second cable-routing channel is partially defined by the second one of the plurality of fan cages and a fourth one of the plurality of fan cages.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of exemplary embodiments together with reference to the accompanying drawings. These drawings depict only exemplary embodiments and, therefore, are not to be considered as limitations on the scope of the various embodiments or claims.

FIG. 1A is a perspective view of a first prior art fan-bracket assembly.

FIG. 1B is a side view of the first prior art fan-bracket assembly of FIG. 1A.

FIG. 2A is a perspective view of a second prior art fan-bracket assembly.

FIG. 2B is a side view of the second prior art fan-bracket assembly of FIG. 2A.

FIG. 3 is a perspective view of a fan-bracket assembly according to the present disclosure.

FIG. 4 is perspective view of one of the fan cages in the fan-bracket assembly of FIG. 3.

FIG. 5A is perspective view of the cage tray in the fan-bracket assembly of FIG. 3.

FIG. 5B is a detailed perspective view of the open end of the cage tray in FIG. 5A.

FIG. 6A is perspective view of the baffle in the fan-bracket assembly of FIG. 3.

FIG. 6B is a detailed perspective view of one of the flanges of the baffle in FIG. 6A.

FIG. 7A is a perspective view illustrating the movement of the fan cage of FIG. 4 within the cage tray of FIGS. 5A-5B;

FIG. 7B is a perspective view illustrating a plurality of fan cages that have been moved into the cage tray according to FIG. 7A.

FIG. 8A is a side view illustrating the protruding portion of the fan cage fitting within the groove of the cage tray according to FIG. 7A.

FIG. 8B is a detailed side view illustrating the protruding portion of the fan cage fitting within the groove of the cage tray from FIG. 8A.

FIG. 9A is an exploded perspective of the cage tray that is being fixed to the baffle.

FIG. 9B is a perspective of the cage tray of FIG. 9A that has been fixed to the baffle.

FIG. 9C is a view of the mating of the baffle and the cage tray in FIG. 9B.

FIG. 10A is a top view of the cage tray mated on the underlying baffle.

FIG. 10B illustrates the distance between the right hole of the baffle for mating with the server chassis and the rightmost opening for a plunger of the rightmost fan cage.

FIG. 10C illustrates the distance between the left mating hole of the baffle for mating with the server chassis and the leftmost opening for a plunger of the leftmost fan cage.

FIG. 10D illustrates the proper alignment of holes of the baffle and the cage tray when the two parts are properly mated.

FIG. 10E illustrates the misalignment of holes of the baffle and the cage tray when the two parts are improperly mated.

FIG. 11A illustrates a fan-bracket assembly according to the present disclosure being mounted into a chassis of a server.

FIG. 11B illustrates the fan-bracket assembly of FIG. 11A after being mounted into a chassis of a server.

FIG. 12A illustrates fans being inserted into the fan cages of the fan-bracket assembly.

FIG. 12B illustrates the fans after insertion into the fan cages of the fan-bracket assembly of FIG. 12B.

FIG. 13 illustrates the actuation of the plunger on the fan cage to unlock the fan cage and allow the fan cage to be moved to a different location in the cage tray.

FIG. 14A illustrates a first possible configuration of the fan cages in the fan-bracket assembly to form a first cable-routing channel on the right side of the fan-bracket assembly.

FIG. 14B illustrates a second possible configuration of the fan cages in the fan-bracket assembly to form a second cable-routing channel in the middle region of the fan-bracket assembly.

FIG. 14C illustrates a third possible configuration of the fan cages in the fan-bracket assembly to form multiple cable-routing channels in the middle region of the fan-bracket assembly.

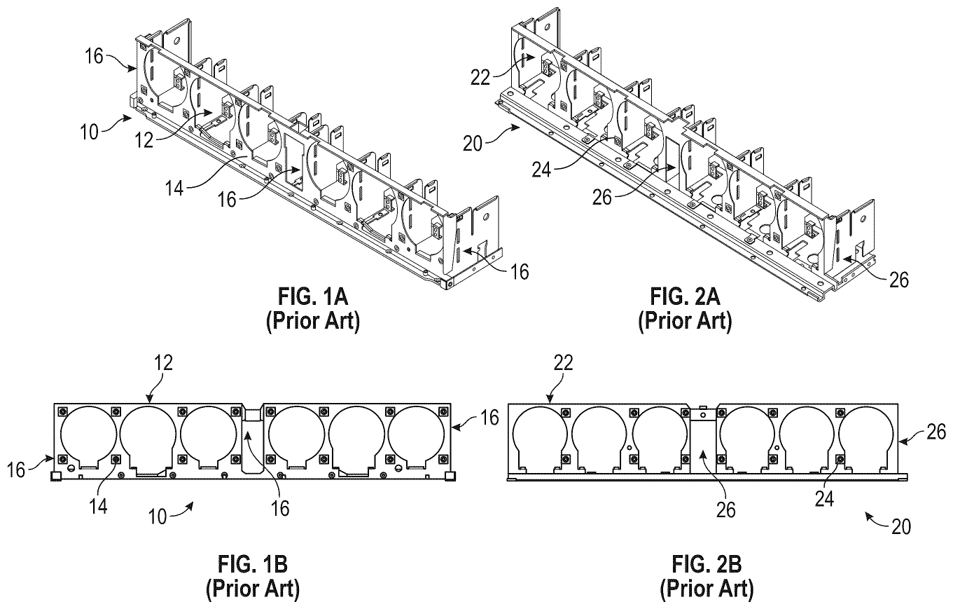

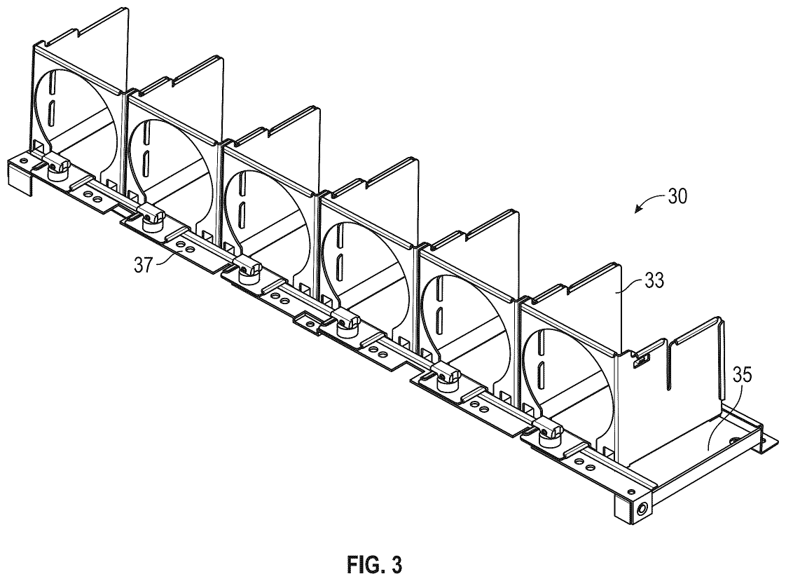

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

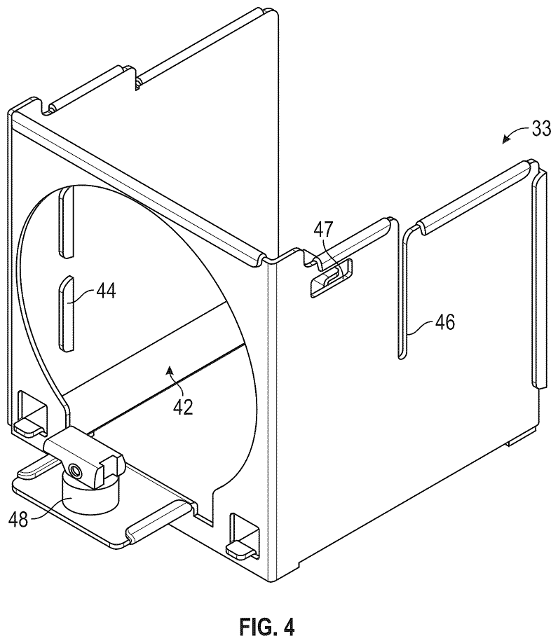

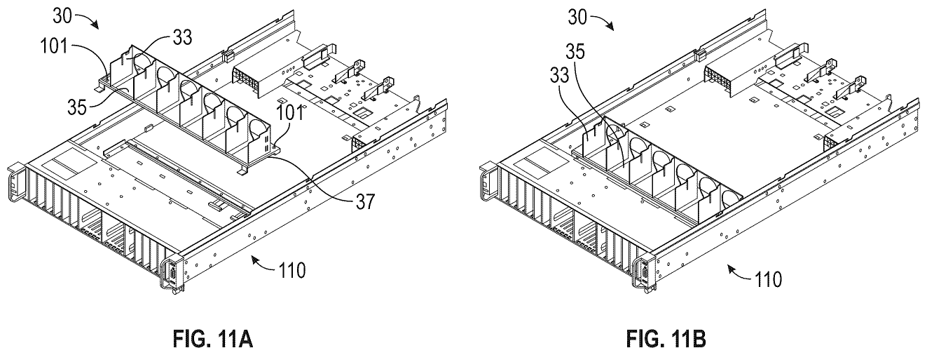

FIG. 3 is a perspective view of a fan-bracket assembly 30 according to the present disclosure. The fan-bracket assembly 30 includes a plurality of fan cages 33, a cage tray 35, a baffle 37 at the bottom of the fan-bracket assembly 30. Each of the fan cages 33 receives a fan that moves air within the chassis of a server for cooling the electronics, as described in more detail in FIGS. 11-13 below.

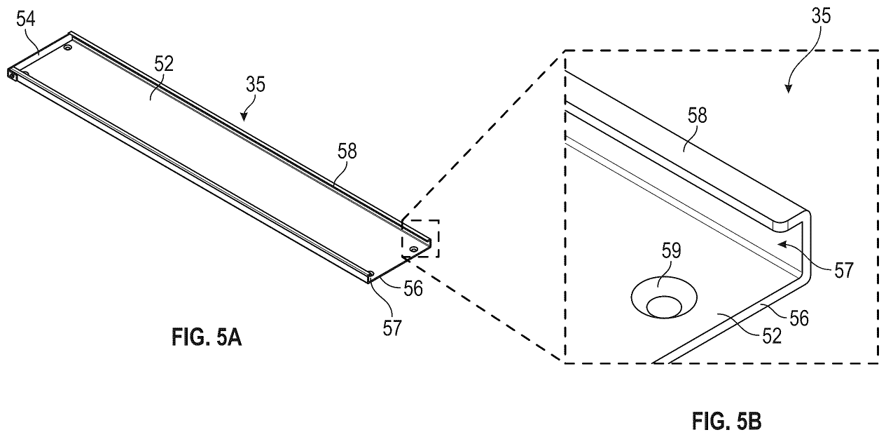

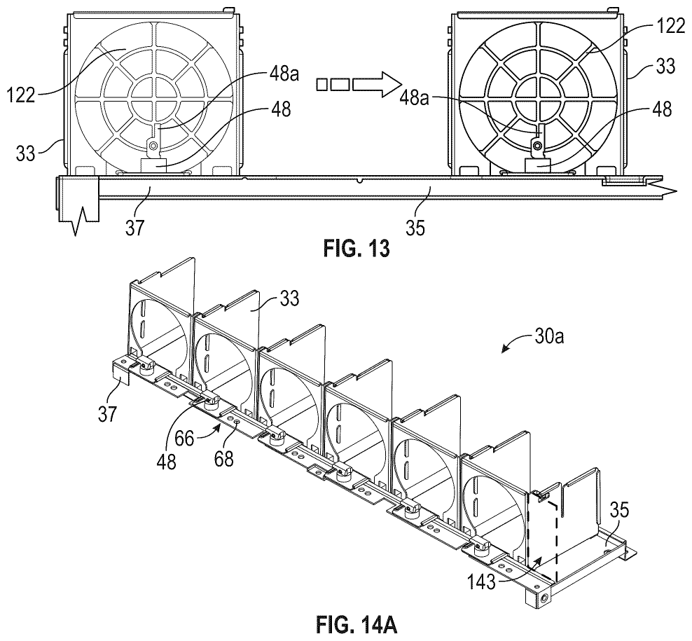

FIG. 4 is perspective view of one of the fan cages 33 (without a fan installed) in the fan-bracket assembly 30 of FIG. 3. The fan cage 33 includes an opening 42 in a front surface through which air can be drawn or pushed by the fan after it is installed. To mount the fan into the fan cage 33, the fan cage 33 includes one or more ribs 44, a slot 46, and/or a hole 47 that mates with corresponding features of the fan. The fan cage 33 also includes a hand-actuated plunger 48 that allows the fan cage 33 to be releasably locked into the fan-bracket assembly 30 (FIG. 3). The function of the plunger 48 of the fan cage 33 is described in more detail in FIG. 13 below.

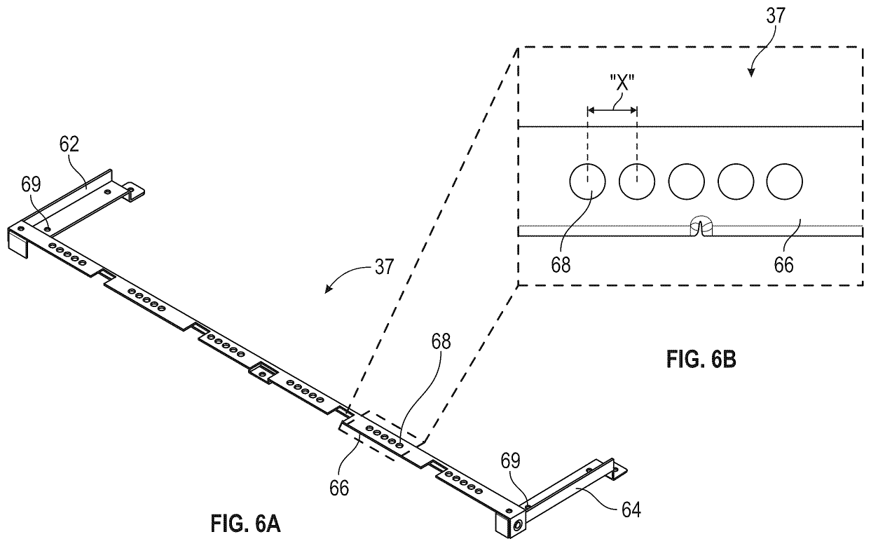

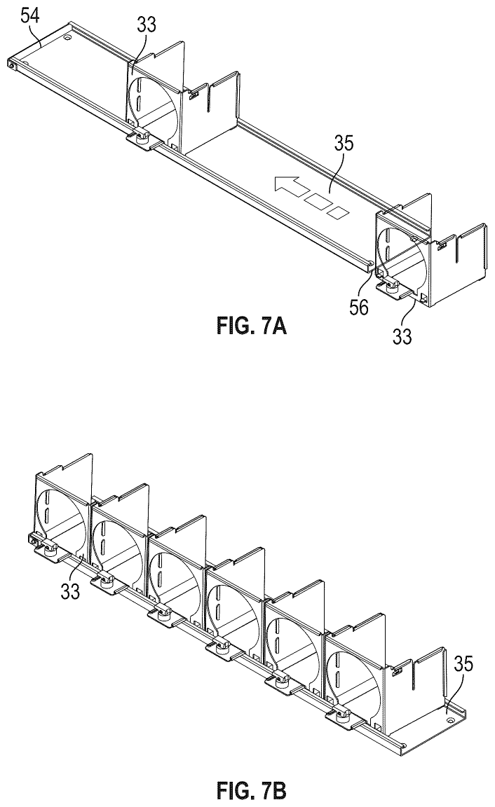

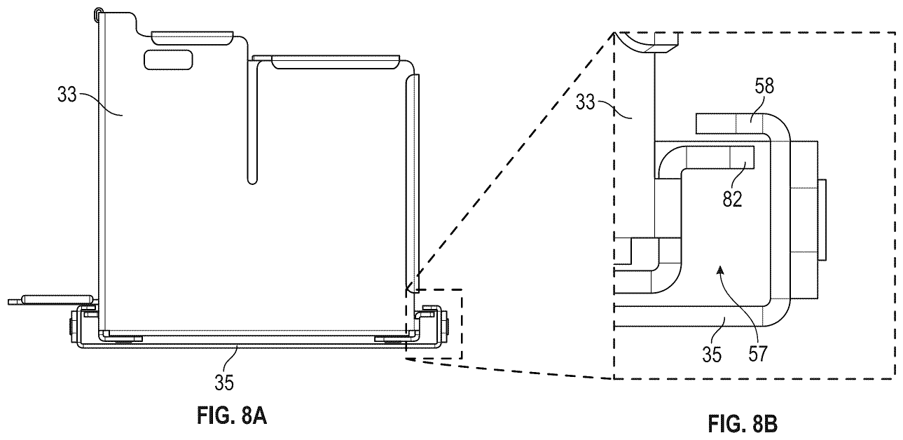

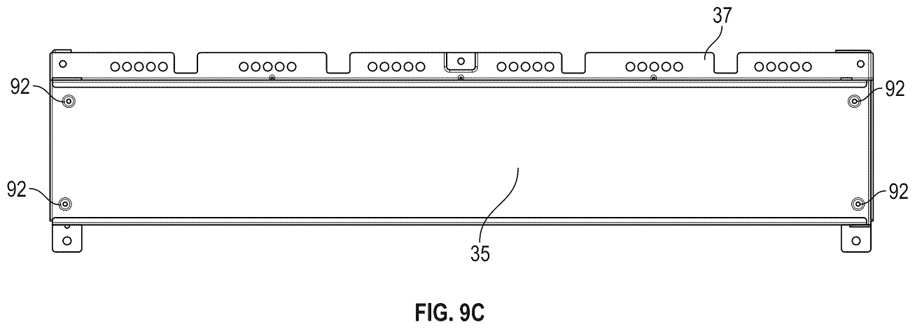

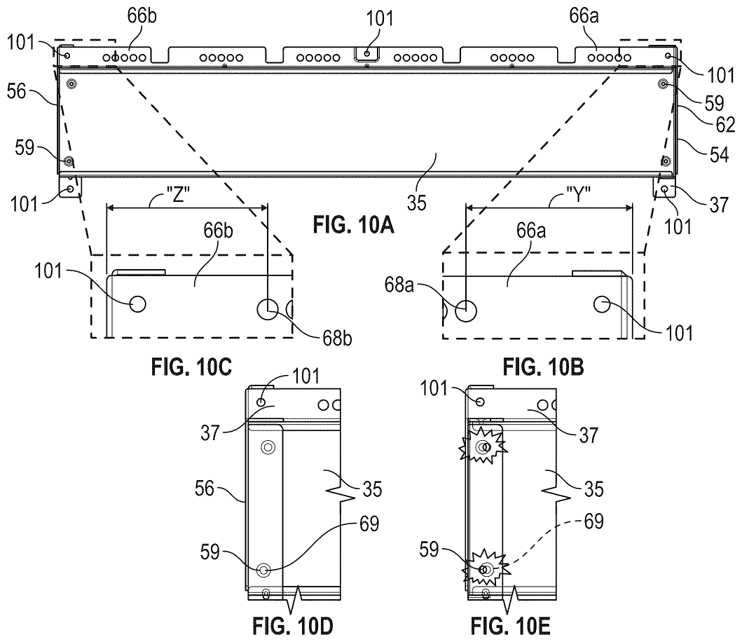

FIG. 5A is perspective view of the cage tray 35 in the fan-bracket assembly 30 of FIG. 3. The cage tray 35 includes a floor 52, a closed end 54, and an open end 56. A pair of side walls 58 extend upwardly from the floor 52. As shown best in FIG. 5B, the side walls 58 are shaped with a bend to define a pair of grooves 57 that are located between the floor 52 and the side wall 58. The grooves 57 are useful for receiving and capturing a plurality of fan cages 33, which is illustrated and described relative to FIGS. 7A-7B. FIG. 5B also illustrates one of the multiple openings 59 in the cage tray 35 for fixing the cage tray 35 to the baffle 37 (FIGS. 6A-6B) of the fan-bracket assembly 30, which is described in more detail in FIGS. 9-10.

FIG. 6A is perspective view of the baffle 37 in the fan-bracket assembly 30 of FIG. 3. The baffle 37 includes a first end 62 and a second end 64, which are used for positioning the cage tray 35 (FIGS. 5A-5B) when these two components are assembled as shown in FIGS. 9A-9C. The baffle 37 includes a plurality of flanges 66 along its length. Each flange 66 includes a plurality of holes 68. A plurality of openings 69 are used to fix the baffle 37 to the openings 59 in the cage tray 35 (FIG. 5B).

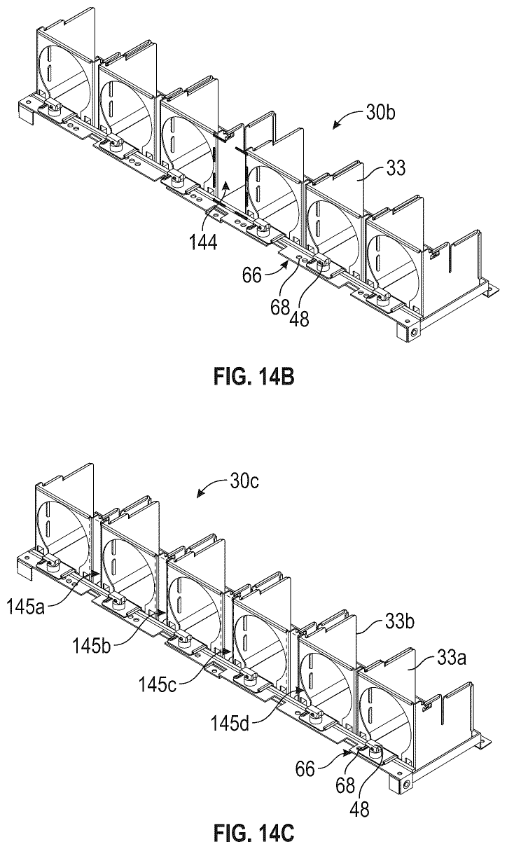

FIG. 6B is a detailed perspective view of one of the flanges 66 of the baffle 37 in FIG. 6A. Each flange 66 has the plurality of holes 68 along the length of the flange 66 that are selectively used to mate with the plunger 48 of the corresponding fan cage 33 (FIG. 4). The holes 68 are spaced apart by a distance “X” such that the fan cage 33 can be mounted in different locations, which assists in defining the location of the cable-routing channels as described in more detail in FIGS. 14A-14C. In some embodiments, the distance “X” is between 5.5 mm and 12 mm. In one particular embodiment, the distance “X” is 6.35 mm such that each fan cage 33 (See FIG. 13) can be moved 25.4 mm (i.e., four increments of 6.35 mm) due the five holes 68 being present in the illustrated embodiment.

FIGS. 7A and 7B illustrate the process of mating the fan cages 33 onto the cage tray 35. Each fan cage 33 is sequentially moved into engagement with the open end 56 of the cage tray 35 and then slid toward the closed end 54. In the illustrated embodiment, six fan cages 33 are mated to the cage tray 35 by this sliding process, as shown in FIG. 7B. In other embodiments, a different number of cage cages 33 can be used.

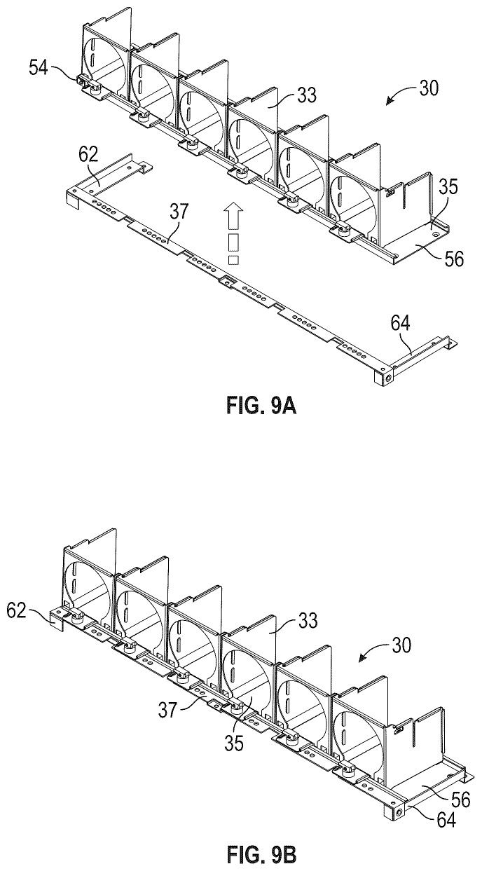

FIG. 8A is a side view illustrating the fan cage 33 being moved into the cage tray 35, according to FIGS. 7A-7B. As shown in the expanded side view of the lower left portion of the cage tray 35 of FIG. 8B, the fan cage 33 includes a protruding portion 82 that fits within the groove 57 of the cage tray 35. Due to the mating of the protruding portions 82 on both sides of the fan cage 33 with the grooves 57 of the cage tray 35, the fan cage 33 can be captured by and held within the cage tray 35, such that the vertical movement of the fan cage 33 is restricted.

FIGS. 9A and 9B illustrate perspectives of the six fan cages 33 captured within the cage tray 35 before and after, respectively, the cage tray 35 is fixed to the baffle 37 in constructing the fan-bracket assembly 30. The cage tray 35 fits within the first end 62 and the second end 64 of the baffle 37, and the open end 56 of the cage tray 35 is closed by the structure of the second end 64 of the baffle 37. Hence, the plurality of fan cages 33 are fully captured within the cage tray 35 because the open end 56 of the cage tray 35 has now been closed.

FIG. 9C is a top view of the mating of the baffle 37 and the cage tray 35 whereby fasteners 92 are passed through the openings 59 (FIG. 5B) of the cage tray 35 and the openings 69 (FIG. 6B) of the baffle 37. In the illustrated embodiment, there are four fasteners 92 that are in the form of rivets, although the number and type of fasteners 92 may be different in other embodiments. Additionally, welding may be used to connect the baffle 37 and the cage tray 35.

FIGS. 10A-10E are various views of the cage tray 35 on the underlying baffle 37 that illustrate how the cage tray 35 is reliably mated to the baffle 37. FIG. 10B illustrates the distance “Y” between (i) a right edge of the baffle 37 and (ii) the rightmost hole 68a on the flange 66a of the baffle 37. FIG. 10C illustrates the distance “Z” between (i) a left edge of the baffle 37 and (ii) the leftmost hole 68b on the flange 66b of the baffle 37. The difference between the distance “Y” and the distance “Z” is approximately the thickness of the sheet metal material of the parts and, specifically, the cage tray 35. This is because the closed end 54 of the tray 35 includes extra material that abuts the first end 62 of baffle 37, whereas the open end 56 of the tray 35 lacks this extra material. In the illustrated embodiment, the distance “Y” is about 35 mm and the distance “Z” is approximately 34 mm, which accounts for the approximate 1 mm of material thickness. FIGS. 10A-10E also illustrate the mating holes 101 on the baffle 37 that allow the fan-bracket assembly 30 to be mounted in the chassis of the server.

To ensure the proper orientation of the cage tray 35 on the baffle 37, the openings 59 in the cage tray 35 and the openings 69 in the baffle 37 are only aligned when the cage tray 35 and the baffle 37 are fitted together in the proper orientation as shown in FIG. 10D, thereby permitting the fasteners 92 (FIG. 9C) to be inserted. As shown in FIG. 10E, if the cage tray 35 and the baffle 37 are incorrectly orientated in the opposite direction, then the openings 59 on the cage tray 35 and the openings 69 are not aligned (i.e., do not overlay each other) to permit the fasteners 92 to be inserted.

FIGS. 11A and 11B illustrate the process of mounting the fan-bracket assembly 30 into a chassis of a server 110. The server 110 typically contains printed circuit boards (PCBs) and electronic modules (e.g., memory storage devices and processors) at different locations within the chassis 12. When considering all of the various electronics within the server 110, the PCBs and electronic modules must be kept at suitable operating temperatures, which is assisted by the movement of air from the fans within the fan-bracket assembly 30.

The mating holes 101 on the baffle 37 receive fasteners that fix the fan-bracket assembly 30 within the chassis of the server 110. Because the fan cages 33 are held on the fan tray 35, and the fan tray 35 is fixed to the baffle 37 via the fasteners 92 (FIG. 9C), the fan cages 33 are held in a fixed position within the server 110. Fans can then be installed into the fan cages 33.

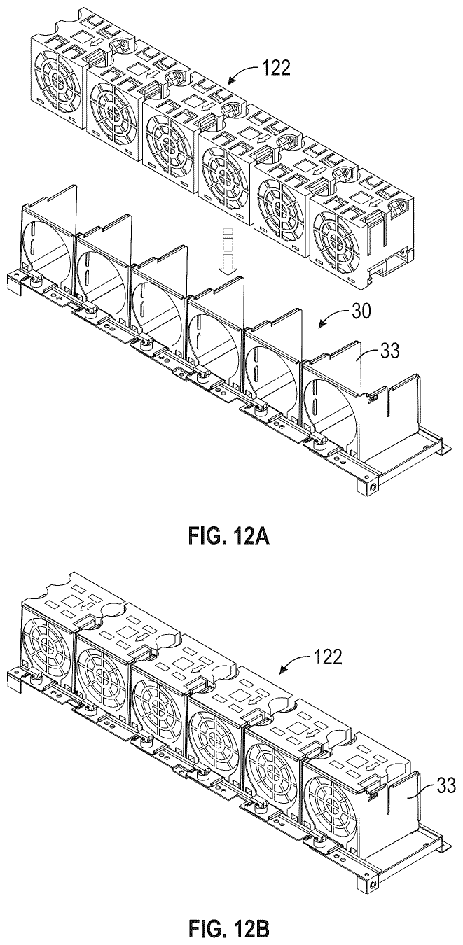

FIGS. 12A and 12B illustrate six fans 122 being inserted into the six fan cages 33 of the fan-bracket assembly 30. The fans 122 include structural features on their external surfaces that mate with one or more of the ribs 44, the slot 46, and the hole 47 of the fan cage 33, which are illustrated in more detail in FIG. 4. Power can be provided to the fans 122 on the lower back side of the fans 122. Alternatively, the fan-bracket assembly 30 can include cut-outs or windows through which wires and/or connectors supply power to the fans 122.

FIG. 13 illustrates the actuation of the plunger 48 on the fan cage 33 to unlock the fan cage 33, allowing the fan cage 33 with the corresponding fan 122 to be moved within the cage tray 35. The plunger 48 has an arm 48a that can be manually moved upwardly without the need for a tool. Each plunger 48 includes a lower pin (not shown) that is designed to fit within the various holes 68 within the flange 66 (FIG. 6B) of the baffle 37. The downward movement of the arm 48a of the plunger 48 causes the corresponding movement of the lower pin of the plunger 48. Once the arm 48a is moved upwardly, the fan cage 33 can slide to the left or right within the cage tray 35. Of course, because there is a plurality of fan cages 33 within the cage tray 35, each of the plungers 48 of the plurality of fan cages 33 need to be actuated to allow all of them to freely slide within the cage tray 35. As such, manual actuation of the plunger 48 allows the fan cage 33 to be movable along the tray 35 and then locked into a proper operational position relative to the tray 35 without the need for tools.

Further, actuation of the plunger 48 allows the fan cage 33 to have its position adjusted to one of the five holes 68 (see FIG. 6B) in the corresponding flange 66 of the baffle 37. Thus, the plunger 48 also allows for minor adjustments (e.g., 6.35 mm, 12.7 mm, 19.05 mm, or 25.4 mm) in the position of the corresponding fan cage 33 to create the required cable-routing channels for passing cables from the front of the fan cages 33 to the back of the fan cages 33.

FIGS. 14A-14C illustrate the beneficial modularity of the fan-bracket assembly 30 in that its overall configuration can be easily modified by the user to accommodate various types of cable-routing arrangements within a server. FIG. 14A illustrates a first configuration for the fan-bracket assembly 30a in which the fan cages 33 form a first cable-routing channel 143 on the right side of the fan-bracket assembly 30a. The user can actuate the plungers 48 of the fan cages 33 with their fingers (i.e., without tools) and slide all of the fan cages 33 to the far left. The plungers 48 can then be actuated downwardly to the operational position, whereby the lower pins of the plungers 48 fit within the leftmost one of the holes 68 on the flanges 66 of the baffle 37 to lock the fan cages 33 into this first configuration. The first cable-routing channel 143 is partially formed by the right outer surface of the rightmost fan cage 33. It is also formed by the underlying exposed tray 35 in this region, as well as an adjacent wall or structure within the server chassis (not shown).

FIG. 14B illustrates a second configuration of the fan-bracket assembly 30b in which the fan cages 33 can define a second cable-routing channel 144 located in the middle region of the fan-bracket assembly 30b. By releasing of the plungers 48, the three left fan cages 33 are moved along the cage tray 35 to the leftmost position. Similarly, the three right fan cages 33 are moved along the cage tray 35 to the rightmost position, yielding the second cable-routing channel 144 between the middle two fan cages of the fan-bracket assembly 30b. The plungers 48 are then actuated back to their operational position, whereby the lower pins of the plungers 48 are locked into the proper holes 68 on the flanges 66 of the baffle 37. As such, the second cable-routing channel 144 is partially formed by the outer surfaces of the middle two fan cages 33.

FIG. 14C illustrates a third configuration for the fan-bracket assembly 30c in which the fan cages 33 form multiple cable-routing channels 145a, 145b, 145c, 145d in the fan-bracket assembly 30c. By releasing of the plungers 48, each of the fan cages 33 is moved left or right, as needed, to form the spaces for the four cable-routing channels 145a, 145b, 145c, 145d between five of the six fan cages 33 such that there is no cable-routing channel between the two rightmost fan cages 33a, 33b. The plungers 48 are then actuated back to their operational position, whereby the lower pins of the plungers 48 fit within the holes 68 on the flanges 66 of the baffle 37 to lock the fan cages 33 into this third configuration for the fan-bracket assembly 30c.

Although FIGS. 14A-14C illustrate the movement of the fan cages 33 within the tray 35 without the fans being mounted, the present disclosure also contemplates embodiments in which the movement of the fan cages 33 within the tray 35 occurs while the fans are also installed. Further, the movement of the fan cages 33 within the tray 35 to create new configurations for the cable-routing channels of the fan-bracket assembly 30 may occur after mounting of the baffle 37 to the server chassis or outside of the server before the mounting of the baffle 37 to the server chassis.

As a skilled artisan would understand, the modularity of the fan-bracket assembly 30 allows for a variety of configurations, whereby the sizes and locations for cable-routing channels are different to accommodate the particular cabling requirements for a particular server. Hence, a single fan-bracket assembly 30 can be manufactured and used in multiple different servers. Further, if the cabling requirements for a particular server are changed (e.g., due to later retrofitting of components within that server), the fan-bracket assembly 30 can be altered to create different cable-routing channels to accommodate the newly changed cabling requirements.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

What is claimed is:

1. A fan-bracket assembly for use in a chassis of a server, the fan-bracket assembly comprising:
a baffle having mounting portions configured for mounting the fan-bracket assembly within the chassis of the server;
a tray that is coupled to the baffle, the tray including a groove;
a plurality of fan cages, each of the plurality of fan cages configured for receiving a fan to move air within the chassis of the server, each of the plurality of fan cages including a protruding section that is received within the groove of the tray such that each of the plurality of fan cages is movable along the tray, each of the plurality of fan cages including a locking element for locking the corresponding fan cage at an operational position relative to the tray; and
a first cable-routing channel partially defined by a first external surface of a first one of the plurality of fan cages, the first cable-routing channel for receiving a first electronics cable that extends from one side of the fan-bracket assembly to an opposing side of the fan-bracket assembly.

2. The fan-bracket assembly of claim 1, wherein the first cable-routing channel is located between the first one of the plurality of fan cages and a second one of the plurality of fan cages, the first cable-routing channel further defined by a second external surface of the second one of the plurality of fan cages.

3. The fan-bracket assembly of claim 1, further including a second cable-routing channel partially defined by a second external surface of a second one of the plurality of fan cages, the second cable-routing channel for receiving a second electronics cable that extends from the one side of the fan-bracket assembly to the opposing side of the fan-bracket assembly.

4. The fan-bracket assembly of claim 1, wherein the mounting portions of the baffle including openings for receiving fasteners that mount the fan-bracket assembly within the chassis of the server.

5. The fan-bracket assembly of claim 1, wherein the locking element includes a hand-actuated plunger that transitions between (i) an open position that allows the corresponding fan cage to be moved along the tray, and (ii) a closed position in which the corresponding fan cage is locked in the operational position, the hand-actuated plunger transitioning between the open position and the closed position without the use of a tool.

6. The fan-bracket assembly of claim 5, wherein the hand-actuated plunger engages one of a plurality of openings on the baffle.

7. The fan-bracket assembly of claim 1, wherein each of the plurality of fan cages includes at least one of a rib and a slit for mating with corresponding features of the fan.

8. The fan-bracket assembly of claim 1, wherein the baffle includes a plurality of flanges that correspond to the plurality of fan cages, and wherein each of the plurality of flanges includes a plurality of mating features for allowing the corresponding fan cage to be mated to the baffle at a plurality of locations.

9. The fan-bracket assembly of claim 1, wherein the tray is coupled to the baffle through a plurality of rivets.

10. The fan-bracket assembly of claim 1, wherein the tray includes a closed end and an open end, the groove extending between the closed end and the open end, each of the plurality of fan cages being insertable into the groove at the open end of the tray and movable toward the closed end of the tray.

11. A fan-bracket assembly for use in servers, the fan-bracket assembly comprising:
a baffle;
a tray that is coupled to the baffle, the tray including a groove;
a plurality of fan cages, each of the plurality of fan cages configured for receiving a fan, each of the plurality of fan cages including a protruding section that is received within the groove of the tray such that each of the plurality of fan cages is movable along the tray, each of the plurality of fan cages including a locking element for locking the corresponding fan cage relative to the tray; and
wherein, in a first configuration, the plurality of fan cages is positioned on the tray to form a first cable-routing channel partially defined by at least a first one of the plurality of fan cages, and
wherein, in a second configuration, the plurality of fan cages is positioned on the tray to form a second cable-routing channel partially defined by at least a second one of the plurality of fan cages, the second cable-routing channel being at a different location relative to the tray than the first cable-routing channel, each of the first and second cable-routing channels being capable of receiving an electronics cable that extends from one side of the fan-bracket assembly to an opposing side of the fan-bracket assembly.

12. The fan-bracket assembly of claim 11, wherein, in the first configuration, the first cable-routing channel is partially defined by the first one of the plurality of fan cages and a third one of the plurality of fan cages.

13. The fan-bracket assembly of claim 12, wherein, in the second configuration, the second cable-routing channel is partially defined by the second one of the plurality of fan cages and a fourth one of the plurality of fan cages.

14. The fan-bracket assembly of claim 11, wherein the baffle has mounting portions adapted for mounting the fan-bracket assembly to (i) a first server when the fan-bracket assembly is in the first configuration and (ii) a second server when the fan-bracket assembly is in the second configuration.

15. The fan-bracket assembly of claim 11, wherein the tray is coupled to the baffle through a plurality of fasteners.

16. The fan-bracket assembly of claim 11, wherein the locking element includes a hand-actuated plunger that moves between (i) an open position that allows the corresponding fan cage to be moved along the tray, and (ii) a closed position in which the corresponding fan cage is locked in a first operational position for the first configuration or locked in a second operational position for the second configuration.

17. A server, comprising:
a chassis having a base and side walls extending upwardly from the base;
electronics located within the chassis;
a first cable and a second cable coupled to the electronics;
a tray fixed within the chassis, the tray including a groove;
a plurality of fan cages, each of the plurality of fan cages including a protruding section that is received within the groove of the tray such that each of the plurality of fan cages is movable along the tray, each of the plurality of fan cages including a locking element for locking the corresponding fan cage relative to the tray; and
a plurality of fans, each of the plurality of fans being mounted within a corresponding one of the plurality of fan cages;
wherein the plurality of fan cages is movable along the tray to form (i) a first configuration having a first cable-routing channel partially defined by at least a first one of the plurality of fan cages and for receiving at least one of the first and second cables, and (ii) a second configuration having a second cable-routing channel partially defined by at least a second one of the plurality of fan cages and for receiving at least one of the first and second cables, the second cable-routing channel being at a different location within the chassis than the first cable-routing channel.

18. The server of claim 17, further including a baffle having mounting portions that are mounted to the chassis of the server, the tray being fixed to the baffle.

19. The server of claim 17, wherein each of the locking elements for the plurality of fan cages is a hand-actuated plunger that allows the plurality of fan cages to be movable along the tray and locked into an operational position without the use of tools.

20. The server of claim 17, wherein, in the first configuration, the first cable-routing channel is partially defined by the first one of the plurality of fan cages and a third one of the plurality of fan cages, and wherein, in the second configuration, the second cable-routing channel is partially defined by the second one of the plurality of fan cages and a fourth one of the plurality of fan cages.
